(19) United States
(12) Patent Application Publication
(10) Pub. No.: US 2015/0114966 A1
(43) Pub. Date: Apr. 30, 2015

(54) PACKAGE, OPTICAL DEVICE, OPTICAL SENSOR, ELECTRONIC DEVICE, AND ELECTRONIC APPARATUS

(71) Applicant: Seiko Epson Corporation, Tokyo (JP)

(72) Inventors: Shigemitsu KOIKE, Suwa (JP); Daisuke SAITO, Matsumoto (JP)

(21) Appl. No.: 14/524,396

(22) Filed: Oct. 27, 2014

(30) Foreign Application Priority Data
Oct. 30, 2013 (JP) 2013-225056

(51) Int. Cl. B65D 13/02; H05K 5/06; H05K 5/02; B65D 85/00; B65D 43/14

(52) U.S. Cl. CPC B65D 13/02; B65D 85/70; B65D 43/14; H05K 5/0239; H05K 5/062
USPC 220/315

(57) ABSTRACT

A container part having an opening portion and a lid part joined by low-melting-point glass and covering the opening portion are provided, and the lid part has a first surface and a second surface intersecting with the first surface, the first surface and the second surface are located inside an outer periphery of the lid part, and the low-melting-point glass joins the container part and the lid part on the first surface and the second surface.

### BACKGROUND

1. Technical Field

The present invention relates to a package, an optical device, an optical sensor, an electronic device, and an electronic apparatus.

2. Related Art

In a package housing an optical element such as a photodiode or a pyroelectric sensor, a glass member for letting in outside light is provided. As a method of joining the glass member to the package, a method using low-melting-point glass as a joining agent is known. For example, low-melting-point glass is applied to the peripheral edge of an opening portion formed in a container part as a main part of the package, and then, a plate-like glass member for covering the opening portion is mounted thereon and joined. The low-melting-point glass of an inorganic material is used as the joining agent so that air-tightness (sealing performance) within the package may be secured, the optical element may be isolated from the external environment, and expected performance (reliability) may be secured.

A crystal vibrator having a crystal piece housed within a package is disclosed in Patent Document 1 (JP-A-2012-104908). According to the document, the crystal piece is provided on a substrate and a lid having a concave portion to cover the crystal piece is provided on the substrate. In this regard, the flat surface of the lid and the flat surface of the substrate are joined. In the third embodiment, the lid and the substrate are joined using low-melting-point glass. The low-melting-point glass has a flat plate shape sandwiched between the flat surface of the lid and the flat surface of the substrate.

When there is a difference in coefficient of thermal expansion between the lid part and the container part, expansion and contraction differ between the lid part and the container part in response to temperature changes. Thereby, stress is generated in the low-melting-point glass. The low-melting-point glass joining the lid part and the container part is a brittle material and cracks are generated therein by application of stress or impact. When the low-melting-point glass has a plate shape, the cracks grow in the planar direction. Then, when the cracks connect between the inside and the outside of the package, a gas flows along the cracks. Thereby, the air-tightness of the package becomes lower. Accordingly, a package that may secure air-tightness even when cracks are generated in a joining agent like low-melting-point glass has been desired.

### SUMMARY

An advantage of some aspects of the invention is to solve the problems described above, and the invention can be implemented as the following forms or application examples.

### Application Example 1

This application example is directed to a package including a container part having an opening portion, a lid part that covers the opening portion, and a joining agent provided between the container part and the lid part, wherein the lid part has a first surface opposed to the opening portion and a second surface intersecting with the first surface, when the lid part is seen from a side of the container part, the second surface is opposed to an outer edge of the container part, and the joining agent is provided between the first surface and the container part, and between the second surface and the container part.

The package includes a container part having an opening portion and a lid part joined to the container part by a joining agent and covering the opening portion, and the lid part has a first surface and a second surface intersecting with the first surface, the first surface and the second surface are located inside an outer periphery of the lid part in a plan view of an opening surface of the opening portion, and the joining agent joins the container part and the lid part on the first surface and the second surface.

According to this application example, the opening portion is provided in the container part. Further, the lid part covers the opening portion of the container part. The container part and the lid part are joined by the joining agent. The lid part has the first surface and the second surface and the first surface and the second surface intersect. Furthermore, the container part and the lid part are joined on the first surface and the second surface.

For joining using the joining agent like low-melting-point glass, the temperature of the joining agent is raised to a melting point, and then, the agent is cooled. When the joining agent is a brittle material and the amount and the speed of contraction are different between the container part and the lid part during cooling, a shear force acts on the joining agent and a crack is liable to be generated. Further, when an impact is applied to the package, a crack may be generated in the joining agent.

When the crack grows in the direction in parallel to the first surface, the crack runs against the second surface intersecting with the first surface or a surface of the container part in a location opposed to the second surface. Therefore, the growth of the crack is blocked. Similarly, when the crack grows in the direction in parallel to the second surface, the crack runs against the first surface intersecting with the second surface or a surface of the container part in a location opposed to the first surface. Therefore, the growth of the crack is blocked. Thereby, the growth of the crack from the inside to the outside of the container part is suppressed. As a result, the air-tightness of the package may be secured.

### Application Example 2

This application example is directed to the package according to the application example described above, wherein the lid part has a third surface intersecting with the second surface, and the joining agent joins the container part and the lid part on the first surface, the second surface, and the third surface.

According to this application example, the lid part has the first surface, the second surface, and the third surface. The first surface intersects with the second surface, and the second surface intersects with the third surface. The crack is generated inside or outside the container part, where stress is higher. Therefore, the crack is generated near the first surface or the third surface. When the crack grows in the direction in parallel to the first surface, the crack runs against the second surface intersecting with the first surface or a surface of the container part in a location opposed to the second surface. Thereby, the growth of the crack is blocked. Similarly, when the crack grows in the direction in parallel to the third surface, the crack runs against the second surface intersecting with the third surface or a surface of the container part in a location opposed to the second surface. Thereby, the growth of the crack is blocked.

The location where the first surface and the second surface intersect and the location where the second surface and the third surface intersect are different. Thereby, the crack generated near the first surface and the crack generated near the third surface are harder to be connected. Therefore, the continuous growth of the crack from the inside to the outside of the container part is suppressed. As a result, the air-tightness of the package may be secured.

### Application Example 3

This application example is directed to the package according to the application example described above, wherein a material of the container part and a material of the lid part are glass or ceramic, and the joining agent is low-melting-point glass.

According to this application example, the material of the container part and the material of the lid part are glass or ceramic, and the joining agent is the low-melting-point glass. When the material of the container part and the material of the lid part are the same, the coefficients of linear expansion are the same. When the low-melting-point glass is cooled, stress is harder to be generated in the low-melting-point glass. The glass and the ceramic are the materials having the coefficients of linear expansion close to each other. Therefore, even in the case where one of the material of the container part and the material of the lid part is glass and the other is ceramic, when the low-melting-point glass is cooled, stress may be made harder to be generated in the low-melting-point glass. As a result, the crack may be harder to be generated in the low-melting-point glass.

### Application Example 4

This application example is directed to the package according to the application example described above, wherein the second surface is a curved surface.

According to this application example, the second surface is the curved surface. When there are air bubbles in the low-melting-point glass before solidification, the pressure is reduced and the air bubbles are removed. In this regard, the air bubbles may be moved along the curved surface, and thereby, the air bubbles may be easily removed from the low-melting-point glass.

### Application Example 5

This application example is directed to the package according to the application example described above, the lid part has a plate shape and the lid part projects from the container part as seen from a thickness direction of the lid part.

According to this application example, the plate-like lid part projects from the container part in the package. The container part is joined to a plate as the material of the container, then, the plate is cut, and thereby, the package may be manufactured. The plate-like lid part projects from the container part, and thus, the container part may be prevented from coming into contact with a blade tool for cutting.

In a method of individually joining one lid part to one container part, handling of providing the lid part on the container part is harder as the package is smaller. Compared to the method, in the method of the application example, the larger container part than the lid part is handled, and thereby, the operation is easier. Therefore, the package may be manufactured with higher productivity.

### Application Example 6

This application example is directed to an optical device in which an optical element is provided in a package, and the package includes a container part having an opening portion, a lid part that covers the opening portion, and a joining agent provided between the container part and the lid part, wherein the lid part has a first surface opposed to the opening portion and a second surface intersecting with the first surface, when the lid part is seen from a side of the container part, the second surface is opposed to an outer edge of the container part, and the joining agent is provided between the first surface and the container part, and between the second surface and the container part.

The optical device is an optical device in which an optical element is provided in a package, and the package includes a container part having an opening portion and a lid part joined by a joining agent and covering the opening portion, and the lid part has a first surface and a second surface intersecting with the first surface, the first surface and the second surface are located inside an outer periphery of the lid part, and the joining agent joins the container part and the lid part on the first surface and the second surface.

According to this application example, the optical element is provided in the package. In the package, the container part and the lid part are joined by the joining agent. A growth of a crack in the joining agent from the inside to the outside of the container part is suppressed. Therefore, the optical device may be an optical device having the optical element provided in the package with ensured air-tightness.

### Application Example 7

This application example is directed to an optical sensor in which an optical sensor element is provided in a package, and the package includes a container part having an opening portion, a lid part that covers the opening portion, and a joining agent provided between the container part and the lid part, wherein the lid part has a first surface opposed to the opening portion and a second surface intersecting with the first surface, when the lid part is seen from a side of the container part, the second surface is opposed to an outer edge of the container part, and the joining agent is provided between the first surface and the container part, and between the second surface and the container part.

The optical sensor is an optical sensor in which an optical sensor element is provided in a package, and the package includes a container part having an opening portion and a lid part joined by a joining agent and covering the opening portion, and the lid part has a first surface and a second surface intersecting with the first surface, the first surface and the second surface are located inside an outer periphery of the lid part, and the joining agent joins the container part and the lid part on the first surface and the second surface.

According to this application example, the optical sensor element is provided in the package. In the package, the container part and the lid part are joined by the joining agent. A growth of a crack in the joining agent from the inside to the outside of the container part is suppressed. Therefore, the optical sensor may be an optical sensor having the optical sensor element provided in the package with ensured air-tightness.

### Application Example 8

This application example is directed to an electronic device in which an electronic element is provided in a package, and the package includes a container part having an opening portion, a lid part that covers the opening portion, and a joining agent provided between the container part and the lid part, wherein the lid part has a first surface opposed to the opening portion and a second surface intersecting with the first surface, when the lid part is seen from a side of the container part, the second surface is opposed to an outer edge of the container part, and the joining agent is provided between the first surface and the container part, and between the second surface and the container part.

The electronic device is an electronic device in which an electronic element is provided in a package, and the package includes a container part having an opening portion and a lid part joined by a joining agent and covering the opening portion, and the lid part has a first surface and a second surface intersecting with the first surface, the first surface and the second surface are located inside an outer periphery of the lid part, and the joining agent joins the container part and the lid part on the first surface and the second surface.

According to this application example, the electronic element is provided in the package. In the package, the container part and the lid part are joined by the joining agent. A growth of a crack in the joining agent from the inside to the outside of the container part is suppressed. Therefore, the electronic device may be an electronic device having the electronic element provided in the package with ensured air-tightness.

### Application Example 9

This application example is directed to an electronic apparatus having an electronic device in which an electronic element is provided in a package, wherein the package includes a container part having an opening portion, a lid part that covers the opening portion, and a joining agent provided between the container part and the lid part, wherein the lid part has a first surface opposed to the opening portion and a second surface intersecting with the first surface, when the lid part is seen from a side of the container part, the second surface is opposed to an outer edge of the container part, and the joining agent is provided between the first surface and the container part, and between the second surface and the container part.

The electronic apparatus is an electronic apparatus having an electronic device in which an electronic element is provided in a package, and the package includes a container part having an opening portion and a lid part joined by a joining agent and covering the opening portion, and the lid part has a first surface and a second surface intersecting with the first surface, the first surface and the second surface are located inside an outer periphery of the lid part, and the joining agent joins the container part and the lid part on the first surface and the second surface.

According to this application example, the electronic apparatus includes the electronic device. In the electronic device, the electronic element is provided in the package. In the package, the container part and the lid part are joined by the joining agent. A growth of a crack in the joining agent from the inside to the outside of the container part is suppressed. Therefore, the electronic apparatus may be an electronic apparatus including the electronic device having the electronic element provided in the package with ensured air-tightness.

### BRIEF DESCRIPTION OF THE DRAWINGS

The invention will be described with reference to the accompanying drawings, wherein like numbers reference like elements.

FIGS. 1A to 1C relate to the first embodiment, and FIG. 1A is a schematic perspective view showing a configuration of a package, FIG. 1B is a schematic side sectional view showing the configuration of the package, and FIG. 1C is a schematic bottom view showing the configuration of the package.

FIGS. 2A and 2B are schematic diagrams for explanation of cracking in low-melting-point glass.

FIGS. 3A to 3D are schematic diagrams for explanation of a method of manufacturing packages.

FIGS. 4A to 4D are schematic diagrams for explanation of the method of manufacturing the packages.

FIGS. 5A and 5B relate to the second embodiment, and FIG. 5A is a schematic side sectional view showing a configuration of a package and FIG. 5B is a schematic sectional view of a main part showing a joining part.

FIGS. 6A to 6C relate to the third embodiment, and schematic side sectional views showing configurations of packages.

FIGS. 7A to 7C relate to the fourth embodiment, and FIG. 7A is a schematic side sectional view showing a structure of an optical sensor, FIG. 7B is a schematic side sectional view showing a structure of an optical scanner, and FIG. 7C is a schematic side sectional view showing a structure of an optical filter.

FIG. 8A is a schematic side sectional view showing a structure of a vibrating device, FIG. 8B is a schematic plan view showing a structure of a vibrator, FIG. 8C is a schematic side sectional view showing a structure of a gyro sensor, and FIG. 8D is a schematic plan view showing a structure of a vibrator.

FIG. 9 is a schematic perspective view showing a sensor light having an optical sensor according to the fifth embodiment.

FIG. 10 is a block diagram showing a configuration of a clock according to the sixth embodiment.

FIG. 11 is a block diagram showing a configuration of a colorimeter according to the seventh embodiment.

FIG. 12 is a schematic front view showing a configuration of a gas detector according to the eighth embodiment.

FIG. 13 is a block diagram showing a configuration of a control system of the gas detector.

FIG. 14 is a block diagram showing a configuration of a food analyzer according to the ninth embodiment.

FIG. 15 is a schematic perspective view showing a configuration of a spectroscopic camera according to the tenth embodiment.

### DESCRIPTION OF EXEMPLARY EMBODIMENTS

In the embodiments, characteristic examples of a package, a method of manufacturing the package, and applications of the package will be explained. As below, the embodiments will be explained with reference to the drawings. Note that the scales of the respective members in the respective drawings are differentiated so that the respective members may have sizes that can be recognized on the respective drawings.

### First Embodiment

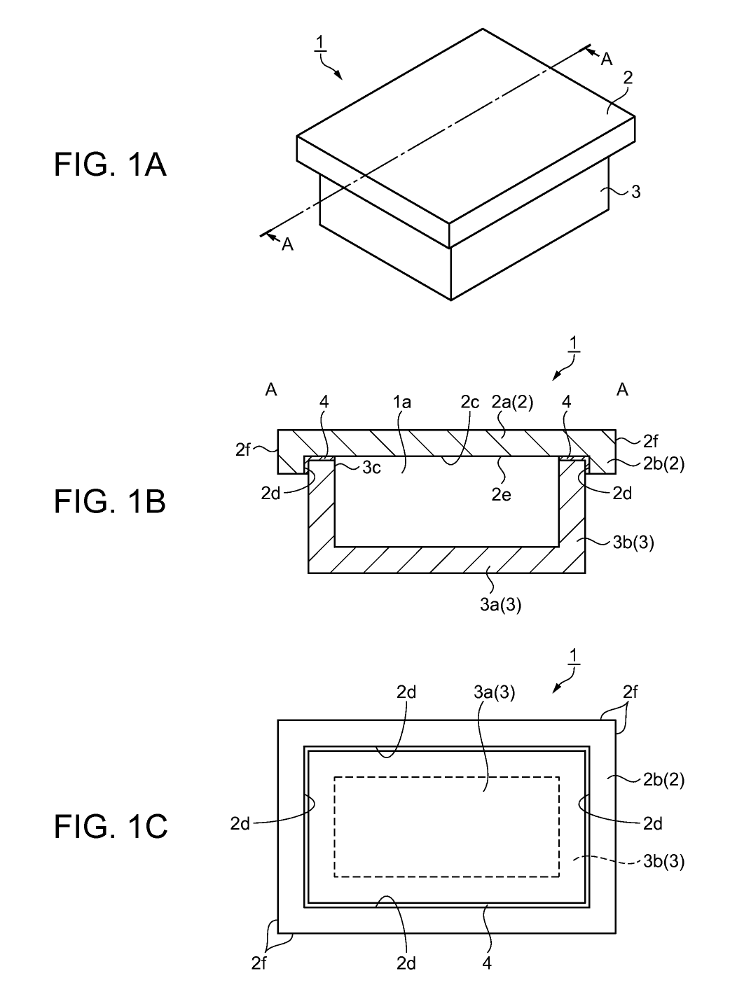

A package according to the first embodiment will be explained with reference to FIGS. 1A to 4D. Inside the package, elements such as an optical element, an optical sensor, and an electronic element may be provided. To make the explanation easily understandable, the elements and wires provided within the package are omitted. FIG. 1A is a schematic perspective view showing a configuration of the package, FIG. 1B is a schematic side sectional view showing the configuration of the package, and a view seen from the surface side taken along line A-A and FIG. 1C is a schematic bottom view showing the configuration of the package.

As shown in FIG. 1A, a package 1 includes a lid part 2 and a container part 3. The container part 3 has a rectangular cylinder shape with a bottom and the lid part 2 has a rectangular plate shape in a plan view. Further, the lid part 2 is provided on the container part 3.

As shown in FIGS. 1B and 1C, the container part 3 has a bottom portion 3a in a rectangular plate shape. A side plate 3b surrounding four sides is stood from the bottom portion 3a. The container part 3 has an opening portion 3c opening upward in the drawing in the location surrounded by the side plate 3b, and the lid part 2 covers the opening portion 3c. Low-melting-point glass 4 as a joining agent is provided between the lid part 2 and the side plate 3b and the low-melting-point glass 4 joins the lid part 2 and the side plate 3b. The low-melting-point glass 4 is provided over the entire periphery of the sideplate 3b and seals an inner portion la of the package 1.

As seen from a thickness direction of the lid part 2, the lid part 2 projects from the container part 3 in the planar direction of the lid part 2. Therefore, the dimensions of the planar shape of the package 1 are the same as the dimensions of the lid part 2. Further, the dimensions of the package 1 may be made accurate by accurate manufacturing of the dimensions of the lid part 2.

The lid part 2 has a rectangular plate-like flat plate portion 2a. A frame portion 2b projecting toward the bottom portion 3a of the container part 3 is provided around the flat plate portion 2a. In the location surrounded by the frame portion 2b, the side facing the bottom portion 3a is a concave portion 2e. The frame portion 2b is provided to surround the side plate 3b with a fixed gap between the side plate 3b and itself. Further, the low-melting-point glass 4 is provided between the frame portion 2b and the side plate 3b.

A surface facing the bottom portion 3a is a first surface 2c in the flat plate portion 2a, and surfaces facing the side plate 3b are second surfaces 2d in the frame portion 2b. The first surface 2c and the second surfaces 2d are located inside an outer periphery 2f of the lid part 2. Further, the low-melting-point glass 4 joints the container part 3 and the lid part 2 on the first surface 2c and the second surfaces 2d.

The materials of the lid part 2 and the container part 3 are not particularly limited, but materials having heat resistance and rigidity are preferable. Further, it is preferable that materials of the lid part 2 and the container part 3 having coefficients of thermal expansion close or equal to each other. For example, for the materials of the lid part 2 and the container part 3, inorganic materials of glass, ceramic, silicon, or the like may be used. In the embodiment, for example, glass is used for the lid part 2 and ceramic is used for the container part 3. The ceramic may be manufactured with high productivity by molding using a die and sintering. Further, for formation with high accuracy, the ceramic may be ground after sintering.

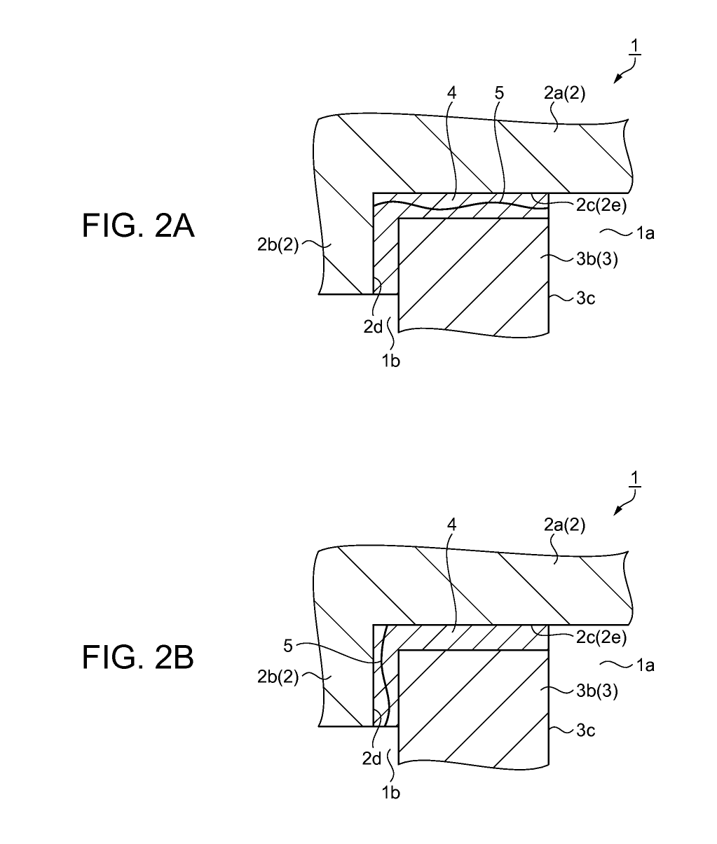

FIGS. 2A and 2B are schematic diagrams for explanation of cracking in low-melting-point glass. As shown in FIG. 2A, the first surface 2a and the second surface 2d are orthogonally provided. Further, the low-melting-point glass 4 fills between the lid part 2 and the container part 3 on the respective surfaces.

When a force acts so that the lid part 2 and the container part 3 move in the lateral direction of the drawing, a shear force acts on the low-melting-point glass 4. Thereby, a crack 5 is formed along a surface nearly in parallel to the first surface 2c in the low-melting-point glass 4. The crack 5 is formed between the inner portion la of the package 1 and the second surface 2d. The crack 5 is generated in a location where stress is higher and grows in the lateral direction of the drawing. The crack 5 grows in a direction in which the shear force is higher and reaches the second surface 2d. Then, the crack 5 stops growing because the second surface 2d is an interface of the low-melting-point glass 4.

As shown in FIG. 2B, when a force acts so that the lid part 2 and the container part 3 move in the longitudinal direction of the drawing, a shear force acts on the low-melting-point glass 4. Thereby, a crack 5 is formed along a surface nearly in parallel to the second surface 2d in the low-melting-point glass 4. The crack 5 is formed between an outer portion 1b of the package 1 and the first surface 2c. The crack 5 is generated in a location where stress is higher and grows in the longitudinal direction of the drawing. The crack 5 grows in a direction in which the shear force is higher and reaches the first surface 2c. Then, the crack 5 stops growing because the first surface 2c is an interface of the low-melting-point glass 4. Therefore, the structure of the package 1 is a structure in which the inner portion la of the package 1 and the outer portion 1b of the package 1 are harder to be connected by the crack 5.

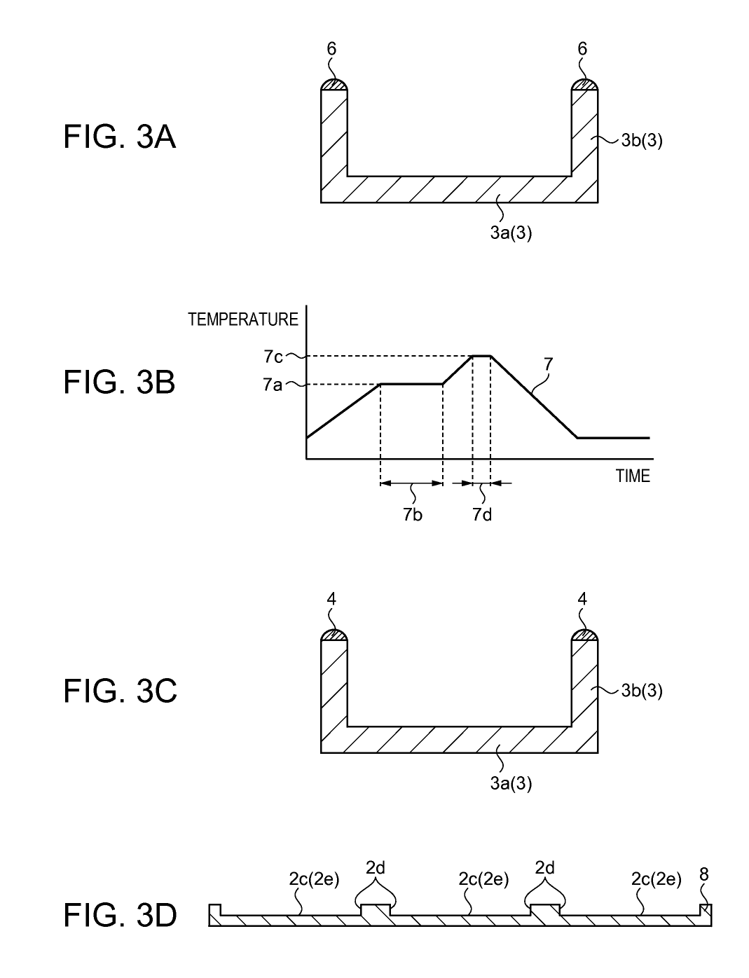

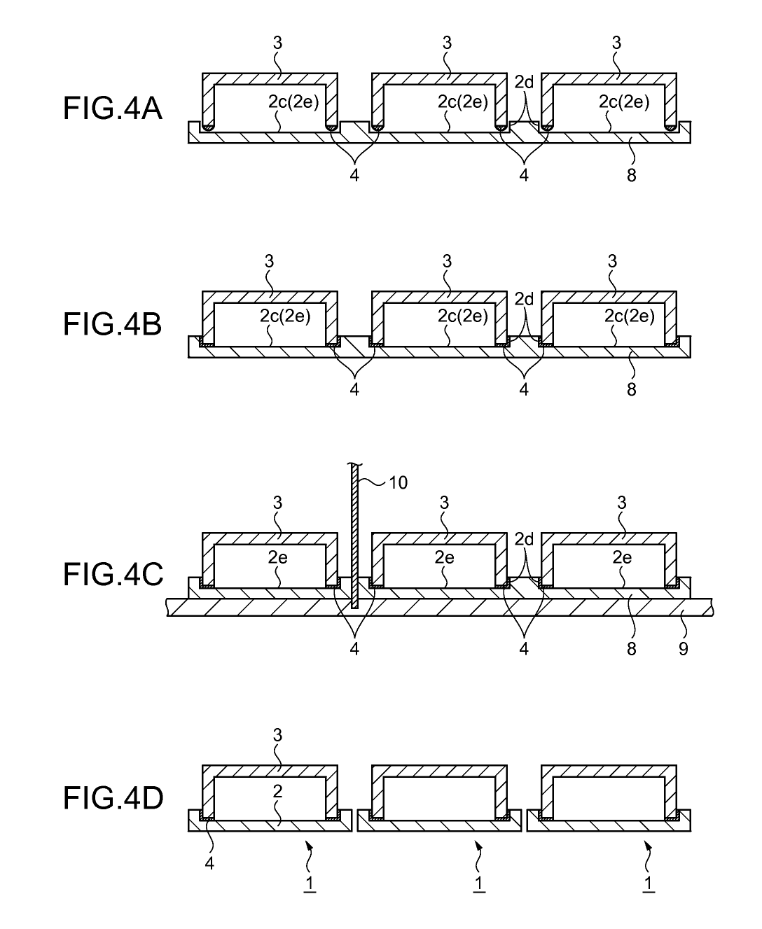

Next, a method of manufacturing the above described package 1 will be explained with reference to FIGS. 3A to 4D. FIGS. 3A to 4D are schematic diagrams for explanation of a method of manufacturing the packages. As shown in FIG. 3A, the container part 3 is prepared. The container part 3 is made of ceramic and formed by molding of a material in a die and sintering. To raise the accuracy of the shape, the outer shape may be ground. The method of manufacturing the ceramic is known and the detailed explanation is omitted.

A glass paste 6 is applied to the entire periphery of the end of the side plate 3b in the container part 3. The glass paste 6 includes the powdered low-melting-point glass 4, volatile binders, etc. The glass paste 6 is in a paste form and has viscosity that can be applied to the container part 3. The method of applying the glass paste 6 to the container part 3 is not particularly limited. For example, screen printing, offset printing, letterpress printing, inkjet printing, or the like may be used for the application method.

Then, the applied glass paste 6 is heated into the form of the low-melting-point glass 4. In FIG. 3B, the vertical axis indicates temperature and the horizontal axis indicates transition of time. A temperature transition line 7 shows transition of a temperature for heating the glass paste 6. The container part 3 to which the glass paste 6 has been applied is placed in an oven or thermostatic chamber and heated. The heating may be performed within an atmosphere of nitride gas or ammonia gas for antioxidation.

First, the glass paste 6 is heated to a first temperature 7a. Then, the first temperature 7a is kept for a first period 7b. Then, the glass paste 6 is heated to a second temperature 7c. Subsequently, the second temperature 7c is kept for a second period 7d. Then, the glass paste 6 is slowly cooled to a normal temperature. The temperatures and the periods are not particularly limited. For example, in the embodiment, the first temperature 7a is about 250° C. and the first period 7b is about 30 minutes. The second temperature 7c is 350° C. and the second period 7d is two minutes. As a result, as shown in FIG. 3C, the glass paste 6 turns to the low-melting-point glass 4 and the low-melting-point glass 4 is provided on the side plate 3b of the container part 3.

Then, as shown in FIG. 3D, a substrate for lid part 8 is prepared. The substrate for lid part 8 is a substrate in which a plurality of the lid parts 2 are arranged, and a plurality of the concave portions 2e having the first surfaces 2c and the second surfaces 2d are formed in the substrate for lid part 8. The number of concave portions 2e is not particularly limited. In the embodiment, three concave portions 2e are provided in one substrate for lid part 8 for simplicity of the drawing.

The first surfaces 2c and the second surfaces 2d may be formed by heating of the substrate for lid part 8 and pressing with a die with convex portions. Otherwise, the first surfaces 2c and the second surfaces 2d may be formed by grinding. The shapes of the first surfaces 2c and the second surfaces 2d may be formed with high accuracy using either of the methods.

Then, as shown in FIG. 4A, the container parts 3 are mounted on the substrate for lid part 8 so that the low-melting-point glass 4 may be in contact with the first surfaces 2c. The container parts 3 are arranged according to the planar shapes of the respective concave portions 2e.

Then, as shown in FIG. 4B, the container parts 3 and the substrate for lid part 8 are heated. The heating condition is not limited as long as the low-melting-point glass 4 is liquefied. In the embodiment, for example, the heating condition is that 350° C. is kept for about two minutes. The load on the low-melting-point glass 4 may be the own weights of the container parts 3, or a jig may be mounted on the container parts 3 and pressure of about 0.03 MP may be applied thereto. As the heating device, an oven, a thermostatic chamber, or a belt furnace may be used. The low-melting-point glass 4 melts and spreads to the first surfaces 2c and the second surfaces 2d, and then, the low-melting-point glass 4 is slowly cooled and solidified. The lid parts 2 and the container parts 3 are joined by the low-melting-point glass 4 in the locations of the first surfaces 2c and the second surfaces 2d.

Then, as shown in FIG. 4C, the substrate for lid part 8 is bonded and fixed to a dicing tape 9. The dicing tape 9 is attached to a frame (not shown). An operator places and fixes the dicing tape 9 with the substrate for lid part 8 thereon in a dicing device (not shown). Then, the substrate for lid part 8 is cut using a rotating dicing saw 10. The lid part 2 after cutting projects from the side plate 3b of the container part 3 in the planar direction of the lid part 2. Further, the position where the substrate for lid part 8 is cut by the dicing saw 10 is apart from the side plate 3b of the container part 3. Therefore, the substrate for lid part 8 may be easily cut while the dicing saw 10 is not contact with the side plate 3b of the container part 3. Then, the substrate for lid part 8 is separated from the dicing tape 9. As a result, the packages 1 are completed as shown in FIG. 4D.

As described above, according to the embodiment, the following advantages may be obtained.

(1) According to the embodiment, the container part 3 and the lid part 2 are joined by the low-melting-point glass 4. The lid part 2 has the first surface 2c and the second surfaces 2d, and the first surface 2c and the second surfaces 2d intersect. Further, the container part 3 and the lid part 2 are joined on the first surface 2c and the second surfaces 2d.

When the crack 5 grows in the direction in parallel to the first surface 2c, the crack 5 runs against the second surface 2d and the growth of the crack 5 is blocked. Similarly, when the crack 5 grows in the direction in parallel to the second surface 2d, the crack 5 runs against the first surface 2c and the growth of the crack 5 is blocked. Therefore, the growth of the crack 5 from the inner portion 1a to the outer portion 1b of the package 1 is suppressed. As a result, air-tightness of the package 1 may be secured.

(2) According to the embodiment, the materials of the container part 3 and the lid part 2 are glass or ceramic. When the material of the container part 3 and the material of the lid part 2 are the same, the coefficients of linear expansion are the same, and stress is hardly generated in the low-melting-point glass 4 even when the low-melting-point glass 4 is cooled. The glass and the ceramic are close in coefficient of linear expansion. Therefore, even when one of the material of the container part 3 and the material of the lid part 2 is glass and the other is ceramic, stress may be made harder to be generated in the low-melting-point glass 4 when the low-melting-point glass 4 is cooled. As a result, the crack 5 may be harder to be generated in the low-melting-point glass 4.

(3) According to the embodiment, the plate-like lid part 2 projects from the container part 3 in the package 1. The container part 3 is joined to the substrate for lid part 8 as the material of the lid part 2, then, the substrate for lid part 8 is cut, and thereby, the package 1 may be manufactured. In this regard, the container part 3 and the dicing saw 10 are not in contact because the plate-like lid part 2 projects from the container part 3.

In a method of individually joining one lid part 2 to one container part 3, as the package 1 is smaller, handling for providing the lid part 2 on the container part 3 is harder. Compared to the method, in the method of the embodiment, the container part 3 larger in the thickness direction than the lid part 2 is handled and operation is easier. Therefore, the package 1 may be manufactured with higher productivity.

### Second Embodiment

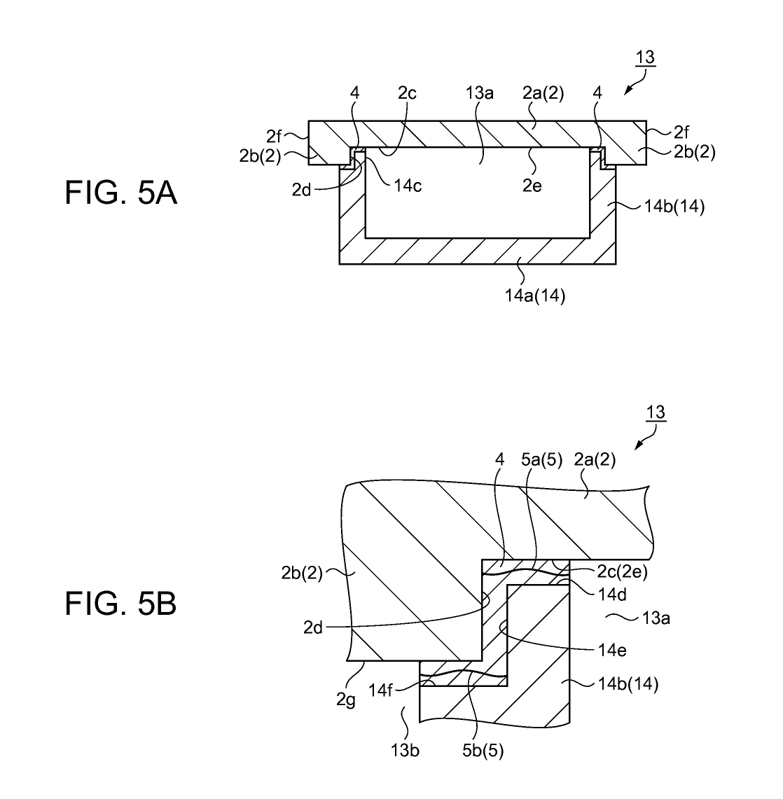

Next, one embodiment of the package will be explained using FIGS. 5A and 5B. FIG. 5A is a schematic side sectional view showing a configuration of a package and FIG. 5B is a schematic sectional view of a main part showing a joining part. The embodiment is different from the first embodiment in that the shape of the location where the lid part 2 and the container part 3 are joined is different. The explanation of the same points as those of the first embodiment will be omitted.

That is, in the embodiment, as shown in FIG. 5A, a package 13 includes a lid part 2 and a container part 14. Further, the lid part 2 is provided on the container part 14. The container part 14 has a rectangular cylinder shape with a bottom and a bottom portion 14a in a rectangular plate shape. A side plate 14b surrounding four sides is stood from the bottom portion 14a. The container part 14 has an opening portion 14c opening upward in the drawing in the location surrounded by the side plate 14b, and the lid part 2 covers the opening portion 14c. Low-melting-point glass 4 is provided between the lid part 2 and the container part 14 and the low-melting-point glass joins the lid part 2 and the container part 14. The low-melting-point glass 4 is provided over the entire periphery of the side plate 14b and the lid part 2 seals an inner portion 13a of the package 13.

As shown in FIG. 5B, a surface facing the bottom portion 14a of the container part 14 is a third surface 2g in a frame portion 2b of the lid part 2. The third surface 2g is orthogonal to a second surface 2d. Further, a step is formed on the end facing the lid part 2 in the side plate 14b. Furthermore, an upper surface 14d in parallel to a first surface 2c is in a location opposed to the first surface 2c. Similarly, an intermediate surface 14e in parallel to the second surface 2d is in a location opposed to the second surface 2d, and a lower surface 14f in parallel to the third surface 2g is in a location opposed to the third surface 2g. The low-melting-point glass 4 joins the container part 14 and the lid part 2 on the first surface 2c, the second surface 2d, and the third surface 2g.

A crack 5 generated between the first surface 2c and the upper surface 14d is a first crack 5a. The first crack 5a grows from an inner portion 13a of the package 13 and stops on the second surface 2d. A crack 5 generated between the third surface 2g and the lower surface 14f is a second crack 5b. The second crack 5b grows from an outer portion 13b of the package 13 and stops on the intermediate surface 14e. Therefore, the structure of the package 13 is a structure in which the inner portion 13a of the package 13 and the outer portion 13b of the package 13 are harder to be connected by the crack 5.

As described above, according to the embodiment, the following advantages may be obtained.

(1) According to the embodiment, the lid part 2 has the first surface 2c, the second surfaces 2d, and the third surface 2g. The first surface 2c intersects with the second surface 2d and the second surface 2d intersects with the third surface 2g. When the crack 5 grows between the first surface 2c and the upper surface 14d, the crack 5 runs against the second surface 2d and the growth of the crack 5 is blocked. Similarly, when the crack 5 grows between the third surface 2g and the lower surface 14f, the crack 5 runs against the intermediate surface 14e and the growth of the crack 5 is blocked.

The location where the first surface 2c and the second surface 2d intersect and the location where the second surface 2d and the third surface 2g intersect are apart. Thereby, the first crack 5a generated in the location near the first surface 2c and the second crack 5b generated in the location near the third surface 2g are harder to be connected. Therefore, the growth of the crack 5 from the inner portion 13a to the outer portion 13b of the package 13 is suppressed. As a result, air-tightness of the package 13 may be secured.

### Third Embodiment

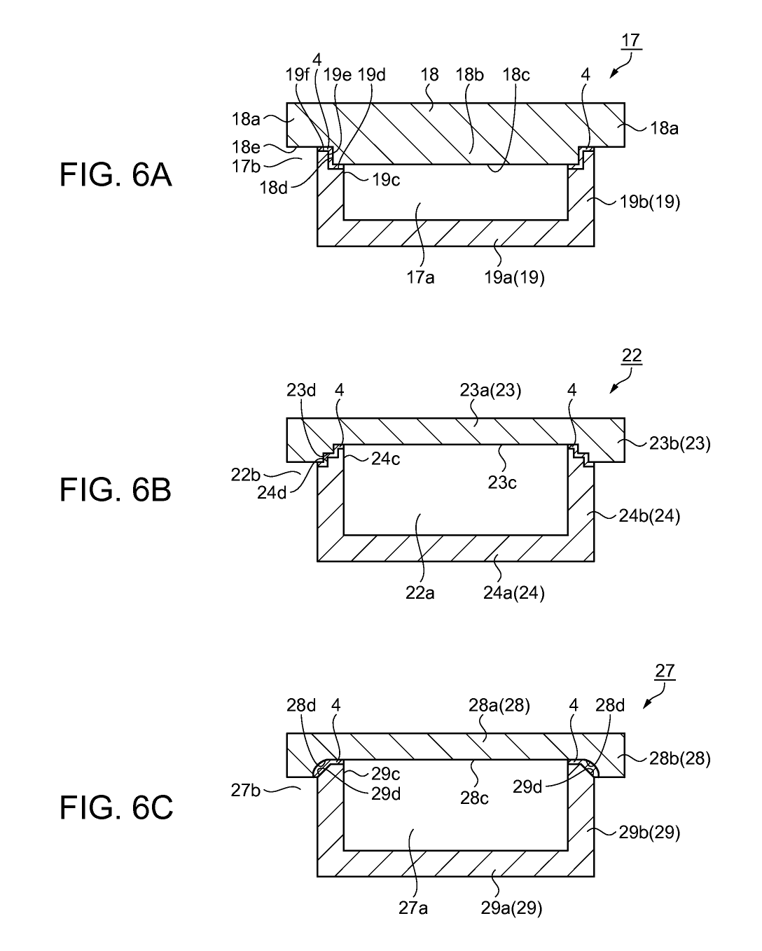

Next, three examples of the embodiment of the package will be explained using FIGS. 6A to 6C. FIGS. 6A, 6B, 6C are schematic side sectional views showing configurations of packages. The embodiment is different from the first embodiment in that the shape of the location where the lid part 2 and the container part 3 are joined is different. The explanation of the same points as those of the first embodiment will be omitted.

That is, in the embodiment, as shown in FIG. 6A, a package 17 includes a lid part 18 and a container part 19. Further, the lid part 18 is provided on the container part 19. The container part 19 has a rectangular cylinder shape with a bottom and a bottom portion 19a in a rectangular plate shape. A side plate 19b surrounding four sides is stood from the bottom portion 19a. The container part 19 has an opening portion 19c opening upward in the drawing in the location surrounded by the side plate 19b, and the lid part 18 covers the opening portion 19c. Low-melting-point glass 4 is provided between the lid part 18 and the side plate 19b and the low-melting-point glass 4 joins the lid part 18 and the side plate 19b. The low-melting-point glass 4 is provided over the entire periphery of the side plate 19b and the lid part 18 seals an inner portion 17a of the package 17.

The lid part 18 includes an outer periphery portion 18a located on the outer periphery and a convex portion 18b located nearer the center than the outer periphery portion 18a and projecting toward the bottom portion 19a. In the convex portion 18b, a surface facing the bottom portion 19a side is a first surface 18c. In the convex portion 18b, a surface facing the outer periphery side is a second surface 18d. In the outer periphery portion 18a, a surface facing the bottom portion 19a side is a third surface 18e. The first surface 18c and the second surface 18d are orthogonal surfaces and the second surface 18d and the third surface 18e are orthogonal surfaces.

A step is formed on the end of the side plate 19b facing the lid part 18. Further, a lower surface 19d in parallel to the first surface 18c is in a location opposed to the first surface 18c. Similarly, an intermediate surface 19e in parallel to the second surface 18d is in a location opposed to the second surface 18d, and an upper surface 19f in parallel to the third surface 18e is in a location opposed to the third surface 18e.

A crack 5 generated between the first surface 18c and the lower surface 19d grows from the inner portion 17a of the package 17 and stops on the intermediate surface 19e. A crack 5 generated between the third surface 18e and the upper surface 19f grows from the outer portion 17b of the package 17 and stops on the second surface 18d. Therefore, the structure of the package 17 is a structure in which the inner portion 17a of the package 17 and the outer portion 17b of the package 17 are harder to be connected by the crack 5.

As shown in FIG. 6B, a package 22 includes a lid part 23 and a container part 24. Further, the lid part 23 is provided on the container part 24. The container part 24 has a rectangular cylinder shape with a bottom and a bottom portion 24a in a rectangular plate shape. A side plate 24b surrounding four sides is stood from the bottom portion 24a. The container part 24 has an opening portion 24c opening upward in the drawing in the location surrounded by the side plate 24b, and the lid part 23 covers the opening portion 24c. Low-melting-point glass 4 is provided between the lid part 23 and the side plate 24b and the low-melting-point glass 4 joins the lid part 23 and the side plate 24b. The low-melting-point glass 4 is provided over the entire periphery of the side plate 24b and seals an inner portion 22a of the package 22.

The lid part 23 includes a rectangular plate-like flat plate portion 23a. A frame portion 23b projecting toward the bottom portion 24a of the container part 24 is provided around the flat plate portion 23a. The location surrounded by the frame portion 23b is a concave portion 23c. The frame portion 23b is provided to surround the side plate 24b at a fixed gap between the side plate 24b and itself.

In the side surface 23d of the concave portion 23c, a surface in the location opposed to the sideplate 24b is formed with steps. Further, the upper surface 24d of the side plate 24b is also formed with steps. The side surface 23d of the concave portion 23c and the upper surface 24d of the side plate 24b are opposed with the low-melting-point glass 4 in between. Thereby, the low-melting-point glass 4 has a shape with corner portions bent at right angles in four locations between the internal portion 22a and the outer portion 22b.

Further, a crack 5 that grows from the inner portion 22a side of the package 22 stops on the side surface 23d of the concave portion 23c. A crack 5 that grows from the outer portion 22b of the package 22 stops on the upper surface 24d of the side plate 24b. Therefore, the structure of the package 22 is a structure in which the inner portion 22a of the package 22 and the outer portion 22b of the package 22 are harder to be connected by the crack 5.

As shown in FIG. 6C, a package 27 includes a lid part 28 and a container part 29. Further, the lid part 28 is provided on the container part 29. The container part 29 has a rectangular cylinder shape with a bottom and a bottom portion 29a in a rectangular plate shape. A side plate 29b surrounding four sides is stood from the bottom portion 29a. The container part 29 has an opening portion 29c opening upward in the drawing in the location surrounded by the side plate 29b, and the lid part 28 covers the opening portion 29c. Low-melting-point glass 4 is provided between the lid part 28 and the side plate 29b and the low-melting-point glass 4 joins the lid part 28 and the side plate 29b. The low-melting-point glass 4 is provided over the entire periphery of the side plate 29b and the lid part 28 seals an inner portion 27a of the package 27.

The lid part 28 includes a rectangular plate-like flat plate portion 28a. A frame portion 28b projecting toward the bottom portion 29a of the container part 29 is provided around the flat plate portion 28a. The location surrounded by the frame portion 28b is a concave portion 28c. The frame portion 28b is provided to surround the side plate 29b at a fixed gap between the side plate 29b and itself.

The side surface 28d as a second surface of the concave portion 28c is a curved surface having a section shape of a circular arc. Further, the upper surface 29d of the side plate 29b is an inclined surface. The side surface 28d of the concave portion 28c and the upper surface 29d of the side plate 29b are opposed with the low-melting-point glass 4 in between. When there are air bubbles in the low-melting-point glass 4 before solidification at the assembly step of the package 27, the air bubbles are removed by reduction of the pressure. In this regard, the air bubbles move along the curved surface of the side surface 28d, and thereby, the air bubbles may be easily removed from the low-melting-point glass 4.

A crack 5 that grows from the inner portion 27a side of the package 27 stops on the side surface 28d of the concave portion 28c. A crack 5 that grows from the outer portion 27b of the package 27 stops on the upper surface 29d of the side plate 29b or the side surface 28d of the concave portion 28c. Therefore, the structure of the package 27 is a structure in which the inner portion 27a of the package 27 and the outer portion 27b of the package 27 are harder to be connected by the crack 5.

### Fourth Embodiment

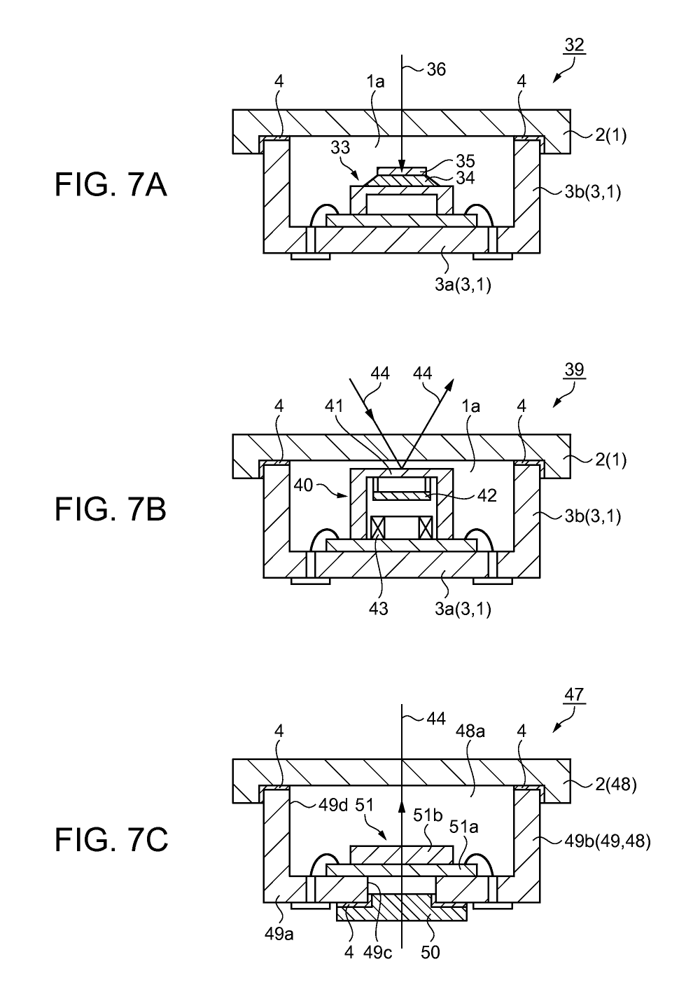

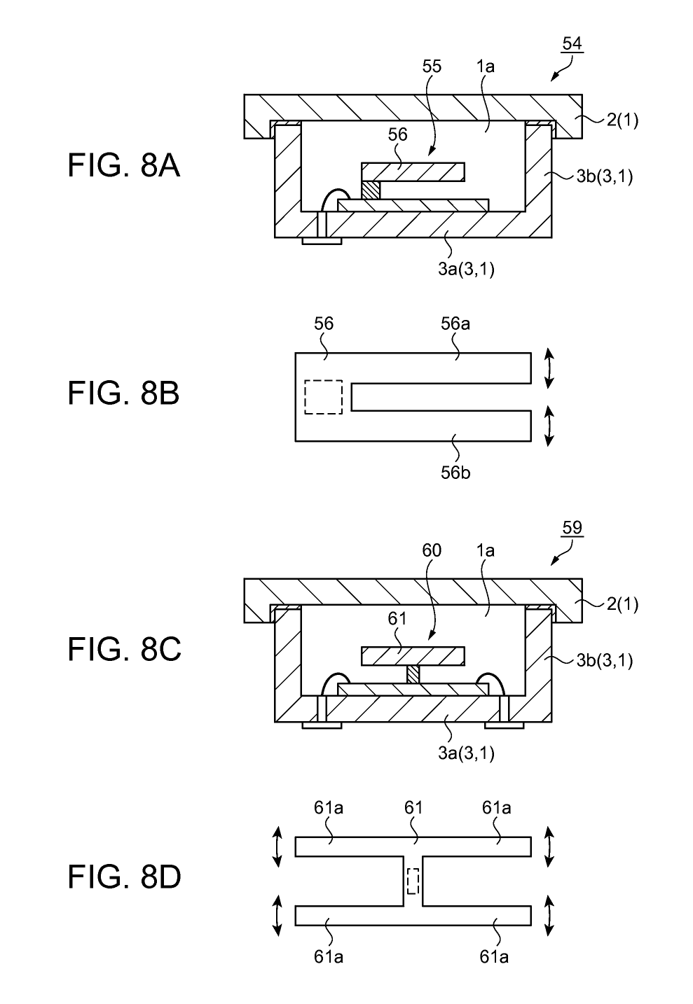

Next, the respective embodiments of the optical device, the optical sensor, the electronic device having the package will be explained using FIGS. 7A to 8D. In the embodiment, the package 1 described in the first embodiment or a package similar to the package 1 is used. The explanation of the same points as those of the first embodiment will be omitted.

FIG. 7A is a schematic side sectional view showing a structure of an optical sensor. That is, in the embodiment, as shown in FIG. 7A, an optical sensor 32 includes the package 1. In the inner portion 1a of the package 1, a sensor element 33 as an optical sensor element is provided on the bottom portion 3a of the container part 3.

The sensor element 33 has a pyroelectric material 34 and an infrared absorbing film 35 is provided on the pyroelectric material 34. When an infrared beam 36 is applied to the optical sensor 32, the infrared beam 36 passes through the lid part 2 and enters the infrared absorbing film 35. The infrared absorbing film 35 absorbs the infrared beam 36 and its temperature rises. The pyroelectric material 34 converts the temperature rise into an electric signal and outputs the signal.

The package 1 of the optical sensor 32 has high air-tightness and the inner portion 1a is decompressed. The temperature of the outside air is harder to transfer to the sensor element 33. Further, the optical sensor 32 is harder to be affected by humidity changes, and may detect the infrared beam 36 with higher accuracy.

FIG. 7B is a schematic side sectional view showing a structure of an optical scanner. That is, in the embodiment, as shown in FIG. 7B, an optical scanner 39 as an optical device and an electronic device includes the package 1. In the inner portion 1a of the package 1, a scanner element 40 as an optical element and an electronic element is provided on the bottom portion 3a of the container part 3.

The scanner element 40 includes a mirror part 41 having a gimbal structure and a magnet 42 is provided in the mirror part 41. An electromagnet 43 is provided in a location opposed to the magnet 42, and the electromagnet 43 allows an electromagnetic force to act on the magnet 42 and swings the mirror part 41. When a beam 44 applies to the optical scanner 39, the beam 44 is reflected by the mirror part 41. Further, the angle and the time of the swing of the mirror part 41 are controlled, and thereby, the direction in which the reflected beam 44 travels is controlled.

The inner portion 1a of the package 1 is decompressed and the mirror part 41 is harder to be subjected to air resistance. Further, the package 1 has higher air-tightness, and the decompressed condition may be maintained for longer period. Furthermore, the mirror part 41 is harder to be oxidized, and the reflectance of the mirror surface may be maintained higher. Therefore, according to the package 1, the life of the optical scanner 39 may be extended.

FIG. 7C is a schematic side sectional view showing a structure of an optical filter. That is, in the embodiment, as shown in FIG. 7C, an optical filter 47 as an optical device and an electronic device includes a package 48. The package 48 includes a container part 49 and the container part 49 has a bottom portion 49a in a rectangular plate shape. An opening portion 49c is provided at the center of the bottom portion 49a and a window part 50 is provided in the opening portion 49c.

The window part 50 is formed using glass. The container part 49 and the window part 50 are joined by low-melting-point glass 4. Further, the connecting structure between the container part 49 and the window part 50 is the same structure as the connecting structure between the container part 3 and the lid part 2 in the first embodiment. Therefore, even when a crack 5 is generated in the low-melting-point glass 4 between the container part 49 and the window part 50, air-tightness of an inner portion 48a of the package 48 may be secured.

A side plate 49b surrounding four sides is stood from the bottom portion 49a. The container part 49 has an opening portion 49d opening upward in the drawing in the location surrounded by the side plate 49b, and the lid part 2 covers the opening portion 49d. Low-melting-point glass 4 is provided between the lid part 2 and the container part 49 and the low-melting-point glass 4 joins the lid part 2 and the container part 49. Further, the connecting structure between the container part 49 and the lid part 2 is the same structure as the connecting structure between the container part 3 and the lid part 2 in the first embodiment. Therefore, even when a crack 5 is generated in the low-melting-point glass 4 between the container part 49 and the lid part 2, air-tightness of an inner portion 48a of the package 48 may be secured.

A filter element 51 as an optical element and an electronic element is provided on the bottom portion 49a of the container part 49 in the inner portion 48a of the package 48. The filter element 51 is an element that functions as a tunable interference filter.

The filter element 51 includes a first substrate 51a and a second substrate 51b. Reflection films are provided on the opposed sides of the first substrate 51a and the second substrate 51b. Further, actuators that change the gap between the reflection films are provided on the first substrate 51a and the second substrate 51b. For example, a mechanism acting on the electrostatic force is used for the actuator. Furthermore, the filter element 51 is adapted to selectively transmit light having a wavelength as twice as the distance between the reflection films.

The actuator is significantly affected by humidity, and it is preferable that the inner portion 48a of the package 48 is maintained at the lower humidity. Further, the package 48 has higher air-tightness, and fluctuations of humidity in the inner portion 48a may be maintained lower. Therefore, the optical filter 47 may accurately control the gap between the reflection films and may accurately select the wavelength of the beam 44 to transmit.

FIG. 8A is a schematic side sectional view showing a structure of a vibrating device, and FIG. 8B is a schematic plan view showing a structure of a vibrator. That is, in the embodiment, as shown in FIG. 8A, a vibrating device 54 as an electronic device includes the package 1. In the inner portion 1a of the package 1, a vibrating element 55 as an electronic element is provided on the bottom portion 3a of the container part 3.

The vibrating element 55 includes a vibrator 56 formed using crystal. As shown in FIG. 8B, the vibrator 56 includes a first arm part 56a and a second arm part 56b. Electrodes are provided on the first arm part 56a and the second arm part 56b, and the element vibrates by application of an alternating-current voltage at a predetermined frequency. The vibrating element 55 is connected to an oscillator circuit (not shown), and thereby, a waveform at a frequency with higher accuracy may be obtained.

Returning to FIG. 8A, the inner portion 1a of the package 1 is decompressed and resistance by a gas when the vibrator 56 vibrates is reduced. Thereby, the vibrator 56 may efficiently vibrate. Further, the package 1 has higher air-tightness and the decompressed condition may be maintained longer. Therefore, according to the package 1, the life of the vibrating device 54 may be extended.

FIG. 8C is a schematic side sectional view showing a structure of a gyro sensor, and FIG. 8D is a schematic plan view showing a structure of a vibrator. That is, in the embodiment, as shown in FIG. 8C, a gyro sensor 59 includes the package 1. In the inner portion 1a of the package 1, a vibrating element 60 as an electronic element is provided on the bottom portion 3a of the container part 3.

The vibrating element 60 includes a vibrator 61 formed using crystal. As shown in FIG. 8D, the vibrator 61 includes four arm parts 61a. Electrodes are provided on the arm parts 61a and the arm parts 61a are vibrated by application of an alternating-current voltage at a predetermined frequency to the electrodes. When the vibrator 61 rotates, the vibration mode of the arm parts 61a changes in response to the rotation speed applied to the arm parts 61a. Further, the rotation speed of the vibrator 61 may be detected using waveforms of the electrodes provided on the arm parts 61a.

The inner portion 1a of the package 1 is decompressed and resistance by a gas when the vibrator 61 vibrates is reduced. Thereby, the vibrator 61 may efficiently vibrate. Further, the package 1 has higher air-tightness and the decompressed condition is maintained longer. Therefore, according to the package 1, the life of the gyro sensor 59 may be extended.

### Fifth Embodiment

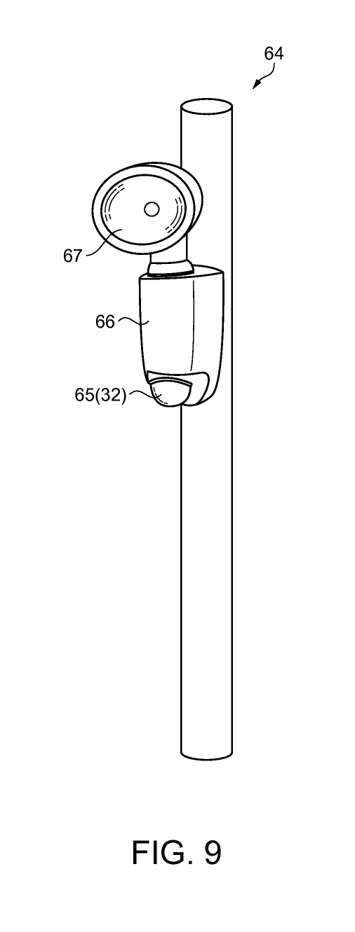

Next, one embodiment of a sensor light including an optical sensor having a package will be explained using FIG. 9. In the embodiment, the optical sensor 32 described in the fourth embodiment is used. The explanation of the same points as those of the fourth embodiment will be omitted.

FIG. 9 is a schematic perspective view showing a sensor light having an optical sensor. The optical sensor 32 may be mounted on a sensor light 64 as an electronic apparatus for use, for example. The sensor light 64 is an illumination apparatus that lights when sensing approach of a person from changes in amount of infrared light, and provided on the porch around the entrance or the like for security.

The sensor light 64 includes a sensor unit 65, a control unit 66, a light 67, etc. The sensor unit 65 includes the optical sensor 32 and a lens for collecting infrared light to the optical sensor 32 etc.

The control unit 66 is an MCU (Micro Controller Unit) that controls the respective parts, and includes a detection part that detects a signal from the sensor unit 65. When the detection part detects the signal from the sensor unit 65, the light 67 is turned on for a fixed period. The light 67 includes an LED element that emits white light, a reflector, etc.

The sensor light 64 has the optical sensor 32 and the optical sensor 32 is protected by the package 1 with higher air-tightness. Therefore, reliable operation may be performed even in the environments with severe temperature changes and humidity changes like outdoors. Thus, the security effect is also expectable.

### Sixth Embodiment

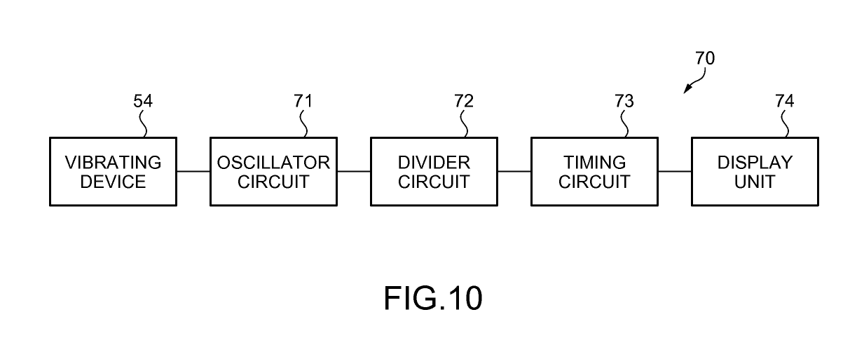

Next, one embodiment of a clock including a vibrating device having a package will be explained using FIG. 10. In the embodiment, the vibrating device 54 described in the fourth embodiment is used. The explanation of the same points as those of the fourth embodiment will be omitted.

FIG. 10 is a block diagram showing a configuration of a clock. The vibrating device 54 may be mounted on a clock 70 as an electronic apparatus for use, for example. The clock 70 is a quartz clock. The clock 70 includes the vibrating device 54 and the vibrating device 54 is connected to an oscillator circuit 71. The oscillator circuit 71 drives the vibrating device 54 to form a voltage waveform at a stable frequency.

The oscillator circuit 71 is connected to a divider circuit 72. The divider circuit 72 converts the voltage waveform output by the oscillator circuit 71 into a voltage waveform at a lower frequency. The divider circuit 72 is connected to a timing circuit 73. The timing circuit 73 measures a lapse of time using the voltage waveform output by the divider circuit 72, and further calculates the current time.

The timing circuit 73 is connected to a display unit 74. When the clock 70 is an analog clock, the display unit 74 includes a motor, a decelerator, a dial face, a hour hand, a minute hand, etc. Further, in the display unit 74, the motor is driven to move the hour hand and the minute hand to locations indicating the current time. When the clock 70 is a digital clock, the display unit 74 includes a liquid crystal display device, a driver circuit, etc. Further, the display unit 74 displays numerals indicating the current time on the liquid crystal display device.

The package 1 having higher air-tightness is used for the vibrating device 54. Therefore, the oscillator circuit 71 may form a voltage waveform at a frequency with higher accuracy. Therefore, the clock 70 may measure times with higher accuracy.

### Seventh Embodiment

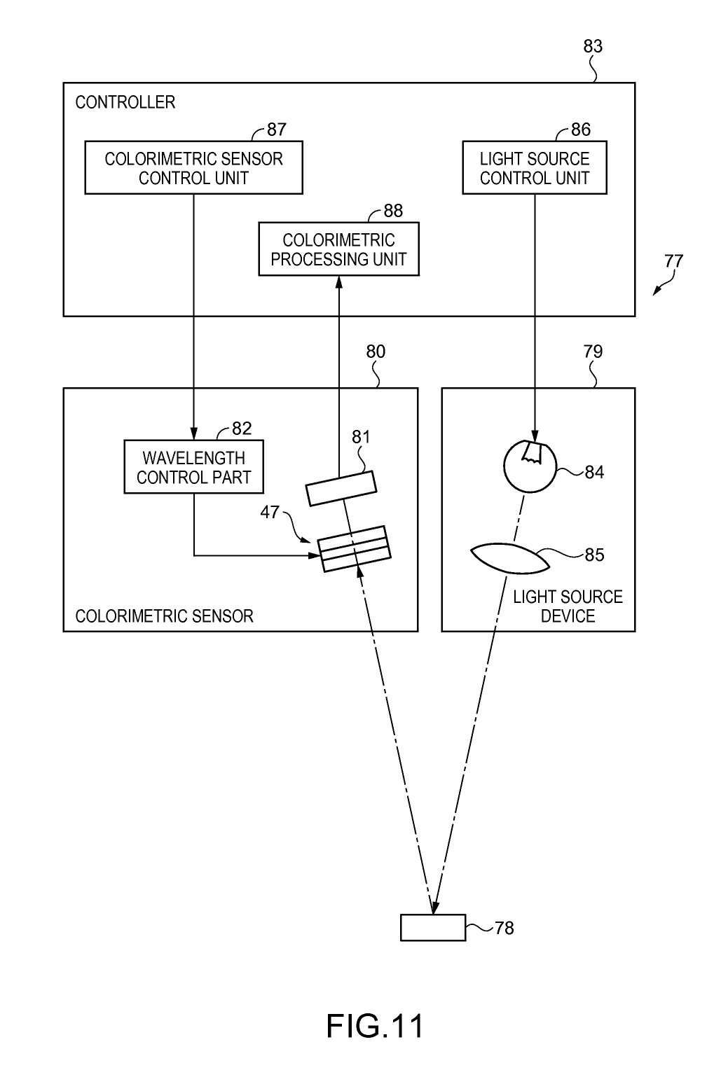

Next, one embodiment of a colorimeter including the optical filter 47 having the package 48 similar to the package 1 will be explained using FIG. 11. In the embodiment, the optical filter 47 described in the fourth embodiment is used. The explanation of the same points as those of the fourth embodiment will be omitted.

### Colorimeter

FIG. 11 is a block diagram showing a configuration of a colorimeter. As shown in FIG. 11, a colorimeter 77 as an electronic apparatus includes a light source device 79 that outputs light to a measuring object 78, a colorimetric sensor (optical module), and a controller 83 that controls the entire operation of the colorimeter 77. Further, the colorimeter 77 allows the light output from the light source device 79 to be reflected by the measuring object 78. The colorimetric sensor 80 receives the reflected light to be inspected, and the colorimeter 77 analyzes and measures chromaticity of the light to be inspected, i.e., the color of the measuring object 78 based on the detection signal output from the colorimetric sensor 80.

The light source device 79 includes a light source 84 and a plurality of lenses 85 (only one is shown in the drawing), and outputs reference light (e.g., white light) to the measuring object 78. Further, the plurality of lenses 85 may include a collimator lens. In this case, the collimator lens parallelizes the reference light output from the light source 84, and the light source device 79 outputs the light from a projection lens (not shown) to the measuring object 78. Note that, in the embodiment, the colorimeter 77 with the light source device 79 is exemplified, however, for example, when the measuring object 78 is a light emitting member such as a liquid crystal panel, a configuration without the light source device 79 may be employed.

The colorimetric sensor 80 includes the optical filter 47, a detector 81 that receives light transmitted through the optical filter 47, and a wavelength control part 82 that controls the wavelength of the light to be transmitted through the optical filter 47. Further, the colorimetric sensor 80 includes an incident optical lens (not shown) in the location opposed to the optical filter 47. The incident optical lens guides the reflection light (light to be inspected) reflected by the measuring object 78 into the colorimetric sensor 80. Then, in the colorimetric sensor 80, a light having a predetermined wavelength of the light to be inspected entering from the incident optical lens is spectroscopically separated by the optical filter 47, and the spectroscopically separated light is received by the detector 81.

The controller 83 controls the entire operation of the colorimeter 77. As the controller 83, for example, not only a general-purpose personal computer or a portable information terminal but also a computer specialized for colorimetry or the like may be used. Further, the controller 83 includes a light source control unit 86, a colorimetric sensor control unit 87, a colorimetric processing unit 88, etc. The light source control unit 86 is connected to the light source device 79 and outputs a predetermined control signal to the light source device 79 to output white light with predetermined brightness based on the settings input by an operator, for example. The colorimetric sensor control unit 87 is connected to the colorimetric sensor 80. For example, the colorimetric sensor control unit 87 sets the wavelength of the light received by the colorimetric sensor 80 based on the settings input by the operator, and the colorimetric sensor control unit 87 outputs a control signal commanding detection of amount of received light of the light at the set wavelength to the colorimetric sensor 80. Thereby, the wavelength control part 82 drives the optical filter 47 based on the control signal. The colorimetric processing unit 88 analyzes the chromaticity of the measuring object 78 from the amount of received light detected by the detector 81.

The optical filter 47 includes the package 48. The package 48 has higher air-tightness, and fluctuations of humidity in the inner portion 48a may be maintained lower. Therefore, the optical filter 47 may accurately control the gap between the reflection films and may accurately select the wavelength of the beam 44 to transmit. As a result, the optical filter 47 may accurately select the wavelength of light to transmit, and thereby, the colorimeter 77 may measure color tone with higher quality.

### Eighth Embodiment

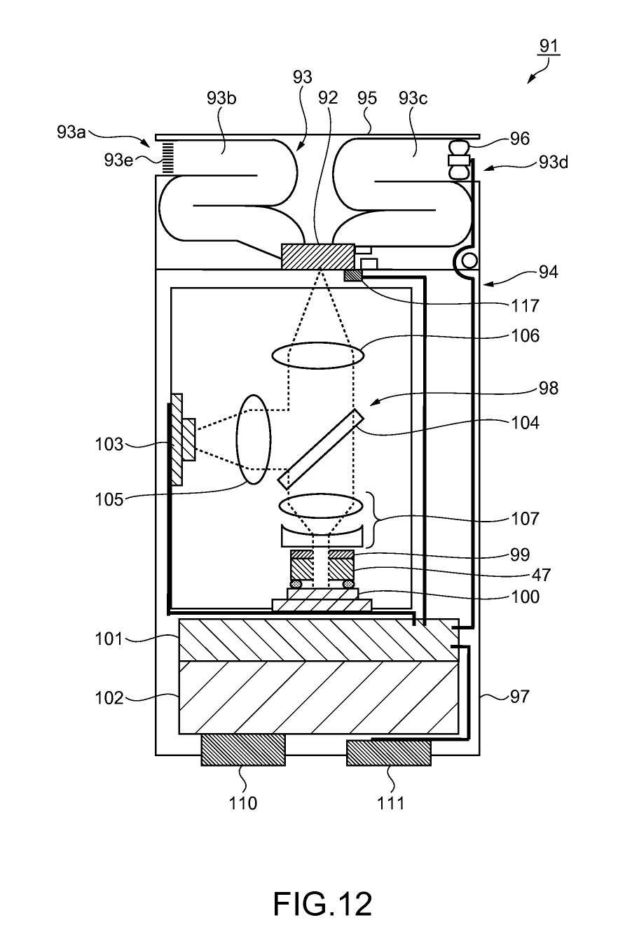

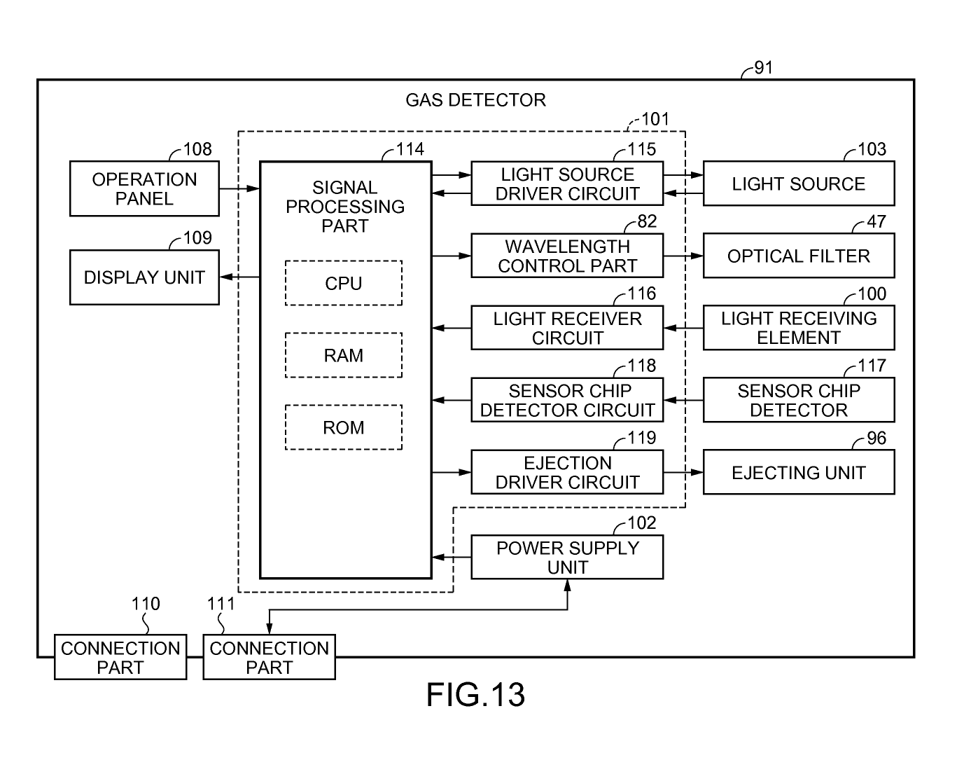

Next, one embodiment of a gas detector including the optical filter 47 having the package 48 similar to the package 1 will be explained using FIGS. 12 and 13. The gas detector is used for an in-car gas leakage detector that detects a specific gas with high sensitivity, a photoacoustic rare gas detector for breath test, or the like, for example. In the embodiment, the optical filter 47 described in the fourth embodiment is used. The explanation of the same points as those of the fourth embodiment will be omitted.

FIG. 12 is a schematic front view showing a configuration of a gas detector, and FIG. 13 is a block diagram showing a configuration of a control system of the gas detector. As shown in FIG. 12, a gas detector 91 as an electronic apparatus including a sensor chip 92, a channel 93 having a suction port 93a, a suction channel 93b, an ejection channel 93c, and an ejection port 93d, and a main body section 94.

The main body section 94 includes a sensor part cover 95 that opens and closes an opening for detachable attachment of the channel 93, an ejecting unit 96, and a casing 97. Further, the main body section 94 has a detection device (optical module) including an optical unit 98, a filter 99, the optical filter 47, and a light receiving element 100 (detection unit), etc. Furthermore, the main body section 94 includes a control unit 101 (processing unit) that processes a detected signal and controls the detection unit, a power supply unit 102 that supplies power, etc. The optical unit 98 includes a light source 103 that outputs light, a beam splitter 104, a lens 105, a lens 106, and a lens 107. The beam splitter 104 reflects the light entering from the light source 103 to the sensor chip 92 side, and transmits the light entering from the sensor chip side to the light receiving element 100 side.

As shown in FIG. 13, in the gas detector 91, an operation panel 108, a display unit 109, a connection part 110 for external interface, and the power supply unit 102 are provided. When the power supply unit 102 is a secondary cell, a connection part 111 for charging may be provided. Further, the control unit 101 of the gas detector 91 has a signal processing part 114 including a CPU etc. and a light source driver circuit 115 for controlling the light source 103. Furthermore, the control unit 101 has a wavelength control part 82 for controlling the optical filter 47 and a light receiver circuit 116 that receives a signal from the light receiving element 100. Moreover, the control unit 101 has a sensor chip detector circuit 118 that reads a code of the sensor chip 92 and receives a signal from a sensor chip detector 117 that detects the presence of the sensor chip 92. In addition, the control unit 101 has an ejection driver circuit 119 that controls the ejecting unit 96 etc.

Next, the operation of the gas detector 91 is explained. The sensor chip detector 117 is provided inside the sensor part cover 95 on the main body section 94. The presence of the sensor chip 92 is detected by the sensor chip detector 117. When detecting the detection signal from the sensor chip detector 117, the signal processing part 114 determines that the sensor chip 92 has attached. Then, the signal processing part 114 sends a display signal for displaying feasibility of the detection operation to the display unit 109.

Then, the operation panel 108 is operated by the operator and an instruction signal commanding start of detection processing is output from the operation panel 108 to the signal processing part 114. First, the signal processing part 114 outputs an instruction signal for driving the light source to the light source driver circuit 115 and activates the light source 103. When the light source 103 is driven, a stable laser beam of single-wavelength linearly-polarized light is output from the light source 103. The light source 103 contains a temperature sensor and a light quantity sensor, and information of the sensors is output to the signal processing part 114. When the signal processing part 114 determines that the light source 103 performs stable operation based on the temperature and the amount of light input from the light source 103, the signal processing part 114 controls the ejection driver circuit 119 to activate the ejecting unit 96. Thereby, a gas sample containing a target substance (gas molecules) to be detected is guided from the suction port 93a, to the suction channel 93b, the inside of the sensor chip 92, the ejection channel 93c, and the ejection port 93d. Incidentally, a dust removing filter 93e is provided in the suction port 93a, and dust powder having relatively large particles, part of steam, etc. are removed.

The sensor chip 92 is an element in which a plurality of metal nanostructures are incorporated and a sensor using a localized surface plasmon resonance. In the sensor chip 92, an enhanced electric field is formed among the metal nanostructures by the laser beam. When the gas molecules enter the enhanced electric field, Raman scattering light and Rayleigh scattering light containing information of molecular vibrations are generated. These Raman scattering light and Rayleigh scattering light pass through the optical unit 98 and enter the filter 99. The Rayleigh scattering light is separated by the filter 99 and the Raman scattering light enters the optical filter 47.

Then, the signal processing part 114 outputs the control signal to the wavelength control part 82. Thereby, the wavelength control part 82 drives the actuators of the optical filter 47 and allows the optical filter 47 to spectroscopically separate the Raman scattering light corresponding to the gas molecules to be detected. When the spectroscopically separated light is received by the light receiving element 100, a light reception signal in response to the amount of received light is output to the signal processing part 114 via the light receiver circuit 116.

The signal processing part 114 compares the obtained spectrum data of the Raman scattering light corresponding to the gas molecules to be detected with data stored in a ROM. Then, the part determines whether or not the gas molecules to be detected are target gas molecules and identifies the substance. Further, the signal processing part 114 displays the result information on the display unit 109 and outputs the information to the outside from the connection part 110.

The gas detector 91 that spectroscopically separates the Raman scattering light by the optical filter 47 and performs gas detection from the spectroscopically separated Raman scattering light has been exemplified. The gas detector 91 may be used as a gas detector that detects absorbance unique to a gas and identifies the kind of the gas. In this case, the optical filter 47 is used for a gas sensor into which a gas is introduced for detecting light absorbed by the gas of incident lights. The gas detector is an electronic apparatus that analyzes and discriminates the gas introduced into the sensor using the gas sensor. The gas detector 91 has the above described configuration, and thereby, may detect the component of the gas using the tunable interference filter.

The optical filter 47 includes the package 48. The package 48 has higher air-tightness, and fluctuations of humidity in the inner portion 48a may be maintained lower. Therefore, the optical filter 47 may accurately control the gap between the reflection films and may accurately select the wavelength of the beam 44 to transmit. As a result, the optical filter 47 may select the wavelength of light to transmit, and thereby, the gas detector 91 may detect the component of the gas with higher quality.

### Ninth Embodiment

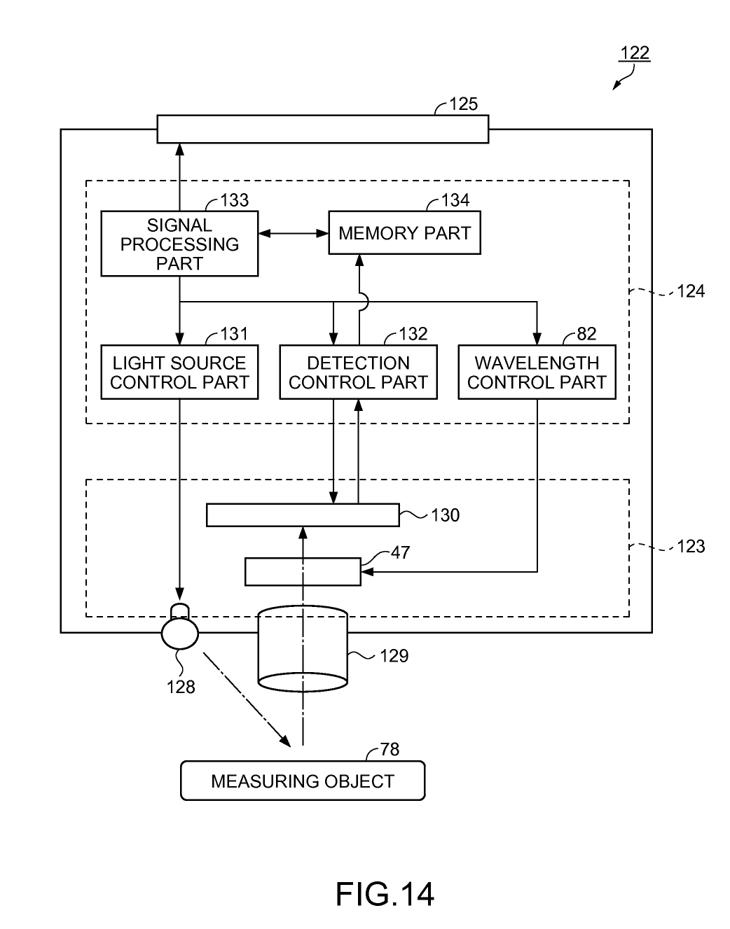

Next, one embodiment of a food analyzer including the optical filter 47 having the package 48 similar to the package 1 will be explained using FIG. 14. The optical filter 47 may be used for a substance component analyzer such as a non-invasive measuring apparatus for sugar using near-infrared spectroscopy or a non-invasive measuring apparatus for information of foods, organisms, minerals, etc. The food analyzer is a kind of substance component analyzer. In the embodiment, the optical filter 47 described in the fourth embodiment is used. The explanation of the same points as those of the fourth embodiment will be omitted.

FIG. 14 is a block diagram showing a configuration of a food analyzer. As shown in FIG. 14, a food analyzer 122 as an electronic apparatus includes a detector 123 (optical module), a control unit 124, and a display unit 125. The detector 123 includes a light source 128 that outputs light, an imaging lens 129 into which light from a measuring object is introduced, and an optical filter 47 that spectroscopically separates the light introduced from the imaging lens 129. Further, the detector 123 includes an imaging unit 130 (detection unit) that detects the spectroscopically separated light. Furthermore, the control unit 124 includes a light source control part 131 that performs turn-on/off control of the light source 128 and brightness control at lighting, and a wavelength control part 82 that controls the optical filter 47. In addition, the control unit 124 includes a detection control part 132 that controls the imaging unit 130 to acquire a spectral image imaged by the imaging unit 130, a signal processing part 133, and a memory part 134.

When the food analyzer 122 is driven, the light source 128 is controlled by the light source control part 131 and light is applied from the light source 128 to a measuring object 78. Then, the light reflected by the measuring object 78 passes through the imaging lens 129 and enters the optical filter 47. The optical filter 47 is driven under the control of the wavelength control part 82. Thereby, a light having a target wavelength may be accurately extracted from the optical filter 47. Then, the extracted light is imaged by the imaging unit 130 including a CCD camera etc., for example. Further, the imaged light is accumulated as a spectral image in the memory part 134. Furthermore, the signal processing part 133 controls the wavelength control part 82 to change the voltage value applied to the optical filter 47 and acquires spectral images with respect to the respective wavelengths.

Then, the signal processing part 133 performs calculation processing on data of the respective pixels in the respective images accumulated in the memory part 134, and obtains spectra in the respective pixels. Further, information on components of foods with respect to the spectra is stored in the memory part 134. The signal processing part 133 analyzes data of the obtained spectra based on the information on the foods stored in the memory part 134. Then, the signal processing part 133 obtains food components contained in the measuring object 78 and contents of the respective food components. Further, the signal processing part 133 may also calculate food calories, freshness, etc. from the obtained food components and the contents. Furthermore, the signal processing part 133 may also perform extraction of apart in which freshness is lower of the food of the measuring object or the like by analyzing the spectrum distribution within an image. In addition, the signal processing part 133 may also detect foreign matter contained in the food or the like. Then, the signal processing part 133 perform processing of displaying the information of components, contents, calories, freshness, etc. of the food to be inspected obtained in the above described manner on the display unit 125.

The optical filter 47 includes the package 48. The package 48 has higher air-tightness, and fluctuations of humidity in the inner portion 48a may be maintained lower. Therefore, the optical filter 47 may accurately control the gap between the reflection films and may accurately select the wavelength of the beam 44 to transmit. As a result, the optical filter 47 may select the wavelength of light to transmit, and thereby, the food analyzer 122 may obtain the food components contained in the measuring object 78 and the contents of the respective food components with higher quality.

Further, in addition to the food analyzer 122, nearly the same configuration may be used as an non-invasive measuring apparatus for other information as described above. For example, the configuration may be used as an organism analyzer that analyzes an organism component for measurement and analysis of body fluid components of blood or the like. As the organism analyzer, for example, the food analyzer 122 may be used for an apparatus that measures the body fluid components of blood or the like. In addition, the food analyzer 122 may be used for an intoxicated driving prevention apparatus that detects the influence of alcohol of a driver as an apparatus that senses ethyl alcohol. Further, the analyzer may be used as an electronic endoscope system including the organism analyzer. Furthermore, the analyzer may be used as a mineral analyzer for component analysis of minerals.

The electronic apparatus using the optical filter 47 may be applied to the following apparatuses. For example, the intensity of the lights having the respective wavelengths is changed over time, and thereby, data may be transmitted by the lights having the respective wavelengths. In this case, a light having a specific wavelength is spectroscopically separated by the optical filter 47 and received by a light receiving part, and thereby, data transmitted by the light having the specific wavelength may be extracted. By processing of the data of the lights having the respective wavelengths with the electronic apparatus that extracts the data using the optical filter 47, optical communication using a plurality of wavelengths may be performed.

### Tenth Embodiment

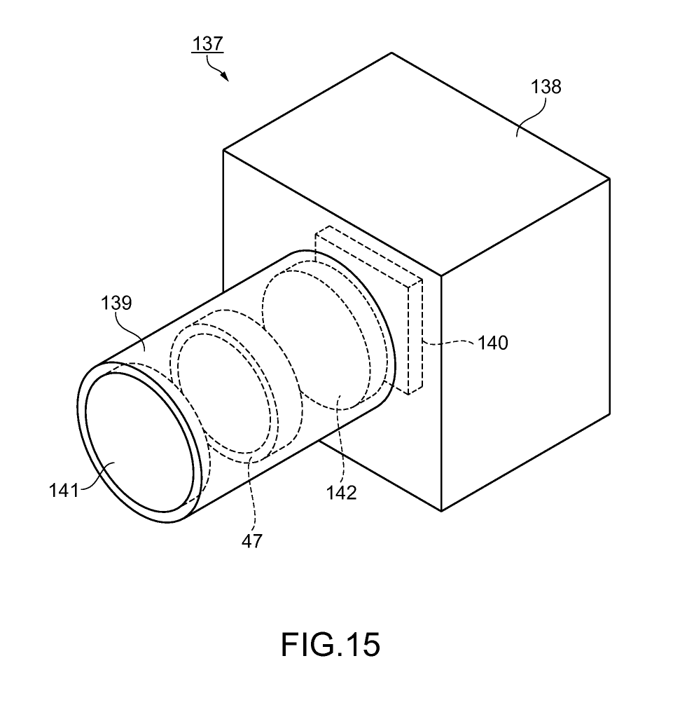

Next, one embodiment of a spectroscopic camera including the optical filter 47 having the package 48 similar to the package 1 will be explained using FIG. 15. The optical filter 47 may be used for a spectroscopic camera that spectroscopically separates light and images a spectral image, a spectroscopic analyzer, or the like. As one example of the spectroscopic camera, an infrared camera containing the optical filter 47 is cited. In the embodiment, the optical filter 47 described in the fourth embodiment is used. The explanation of the same points as those of the fourth embodiment will be omitted.

FIG. 15 is a schematic perspective view showing a configuration of a spectroscopic camera. As shown in FIG. 15, a spectroscopic camera 137 as an electronic apparatus includes a camera main body 138, an imaging lens unit 139, and an imaging unit 140. The camera main body 138 is a part grasped and operated by an operator.

The imaging lens unit 139 is connected to the camera main body 138 and guides incident image light to the imaging unit 140. Further, the imaging lens unit 139 includes an objective lens 141, an image forming lens 142, and the optical filter 47 provided between the lenses. The imaging unit 140 includes a light receiving element and images the image light guided by the imaging lens unit 139. In the spectroscopic camera 137, the optical filter 47 transmits light having a wavelength to be imaged and the imaging unit 140 images a spectral image of the light having a desired wavelength.

The optical filter 47 includes the package 48. The package 48 has higher air-tightness, and fluctuations of humidity in the inner portion 48a may be maintained lower. Therefore, the optical filter 47 may accurately control the gap between the reflection films and may accurately select the wavelength of the beam 44 to transmit. As a result, the optical filter 47 may select the wavelength of light to transmit, and thereby, the spectroscopic camera 137 may accurately image a spectral image with a limited desired wavelength.

Further, an optical module in which the optical filter 47 is incorporated may be used as a bandpass filter. For example, the module may be used as an optical laser apparatus that spectroscopically separates and transmits only lights in a narrow range around a predetermined wavelength of lights in a predetermined wavelength range output by a light emitting device using the optical filter 47. Further, the optical module may be used as a biometric authentication apparatus and applied to an authentication apparatus for blood vessel, fingerprint, retina, iris, or the like using lights in the near-infrared range or visible range. Furthermore, the optical module may be used for a concentration detection apparatus. In this case, infrared energy (infrared light) output from a substance is spectroscopically separated and analyzed by the optical filter 47, and the concentration of a subject in a sample is measured.

As described above, the optical filter 47 may be applied to any apparatus that spectroscopically separates a predetermined light from incident lights. Further, the optical filter 47 may spectroscopically separate a plurality of wavelengths as described above, and thereby, measurement of spectra of the plurality of wavelengths and detection with respect to a plurality of components may be accurately performed. Therefore, compared to an apparatus in related art that extracts a desired wavelength using a plurality of optical filters for spectroscopically separating single wavelengths, downsizing of the electronic apparatus may be promoted and may be preferably used as a portable or in-car optical device. In this regard, the optical filter 47 may also accurately select the wavelength of light to transmit, and thereby, the optical device may accurately limit and use light having a desired wavelength.

Note that the embodiments are not limited to the above described embodiments, but various changes and improvements may be made within the technological scope of the invention by a person who has ordinary knowledge in the field. Modified examples will be described as below.

### Modified Example 1

In the first embodiment, the glass paste 6 is applied to the container part 3 and heated, and thereby, the low-melting-point glass 4 is provided on the container part 3. Not limited to that, but the glass paste 6 may be applied to the concave portions 2e of the substrate for lid part 8 and heated, and thereby, the low-melting-point glass 4 may be provided on the substrate for lid part 8. Then, the container parts 3 may be mounted on the substrate for lid part 8, and heated and joined. The glass paste 6 may be provided in the concave portions 2e of the substrate for lid part 8 by single operation, and thereby, the glass paste 6 may be provided with higher productivity.

### Modified Example 2

In the first embodiment, the container parts 3 are joined to the substrate for lid part 8, and then, the substrate for lid part 8 is cut. Not limited to that, but lid parts 2 may be formed in advance. Further, the container part 3 and the lid part 2 may be joined. They are formed one by one, and thereby, only the necessary number of packages 1 may be assembled. Note that the glass paste 6 may be applied to the lid part 2 and heated, and thereby, the low-melting-point glass 4 may be provided thereon. Or, the glass paste 6 may be applied to the container part 3 and heated, and thereby, the low-melting-point glass 4 may be provided thereon. The easier operation may be selected.

### Modified Example 3

In the first embodiment, the first surface 2c is orthogonal to the second surface 2d, however, the surfaces may intersect at a predetermined angle. In this case, the growth of the crack 5 may be suppressed. Similarly, in the second embodiment, the third surface 2g is orthogonal to the second surface 2d, however, the surfaces may intersect at a predetermined angle. In this case, the growth of the crack 5 may be suppressed.

### Modified Example 4

In the first embodiment, the planar shapes of the lid part 2 and the container part 3 as seen from the thickness direction are rectangular shapes. However, the planar shapes of the lid part 2 and the container part 3 may be polygonal shapes and may be formed in various shapes including circular shapes and oval shapes.

### Modified Example 5

In the first embodiment, glass is used for the lid part 2 and ceramic is used for the container part 3. Ceramic may be used for the lid part 2 and glass may be used for the container part 3. In addition, the same glass or ceramic may be used as the materials of the lid part 2 and the container part 3. In this case, the coefficients of thermal expansion of the materials of the lid part 2 and the container part 3 may be made closer to each other. Therefore, generation of the crack 5 in the low-melting-point glass 4 due to heat may be suppressed. Or, a resin material, resin mixed with fibers, stone, ore, or the like may be used. The materials may be selected to suit the environment in which the package 1 is used.

### Modified Example 6

In the first embodiment, the low-melting-point glass 4 is provided between the lid part 2 and the side plate 3b of the container part 3. The low-melting-point glass 4 may be provided to further project from between the lid part 2 and the side plate 3b of the container part 3 toward the inner portion 1a of the package 1. Further, the low-melting-point glass 4 may be provided to further project from between the lid part 2 and the side plate 3b of the container part 3 toward the outer portion 1b of the package 1. By increase of the area in which the low-melting-point glass 4 is in contact with the lid part 2 and the container part 3, the adhesion may be increased.

### Modified Example 7

In the fourth embodiment, the sensor element 33 is provided on the bottom portion 3a of the container part 3 in the optical sensor 32. Further, the lid part 2 is provided on the container part 3. The sensor element 33 may be provided on the lid part 2. The structure in which the sensor element 33 is provided may be a structure that is easily manufactured. The configurations may be applied to the optical scanner 39, the optical filter 47, the vibrating device 54, and the gyro sensor 59.

### Modified Example 8

In the fourth to tenth embodiments, the package 1 of the first embodiment or the package 48 similar to the package 1 is used. Not limited to the package 1, but the package 13 of the second embodiment, the package 17 of the third embodiment, the package 22, the package 27, and packages similar to them may be used for the respective devices and apparatuses.

Note that the configurations of the modified examples 1 to 6 may be applied to the second embodiment and the third embodiment.

### Modified Example 9

In the first embodiment, the low-melting-point glass 4 is used for the joining agent of the package 1. For the joining agent, polyimide resin or a joining agent having affinity for the materials of the lid part 2 and the container part 3 may be used. A joining agent with higher application operability and a joining agent with higher bonding strength may be used. Further, the configurations may be applied to the package 13 of the second embodiment, the package 17 of the third embodiment, the package 22, and the package 27.

The entire disclosure of Japanese Patent Application No. 2013-225056, filed Oct. 30, 2013 is expressly incorporated by reference herein.

What is claimed is:

1. A package comprising:
a container part having an opening portion;
a lid part that covers the opening portion; and
a joining agent disposed between the container part and the lid part,
wherein the lid part has a first surface opposing to the opening portion and a second surface intersecting with the first surface,
when the lid part is seen from a side of the container part, the second surface is opposed to an outer edge of the container part, and
the joining agent is disposed between the first surface and the container part, and between the second surface and the container part.

2. The package according to claim 1, wherein the second surface is located to be opposed to an outer periphery of the lid part.

3. The package according to claim 1, wherein the lid part has a third surface intersecting with the second surface, and
the joining agent is disposed between the third surface and the container part.

4. The package according to claim 1, wherein a material of the container part and a material of the lid part are glass or ceramic, and the joining agent is low-melting-point glass.

5. The package according to claim 1, wherein the second surface is a curved surface.

6. The package according to claim 1, wherein the lid part has a plate shape and an outer periphery of the lid part projects from the container part as seen from a thickness direction of the lid part.

7. An optical device in which an optical element is disposed in a package,
the package comprising:
a container part having an opening portion;
a lid part that covers the opening portion; and
a joining agent disposed between the container part and the lid part,
wherein the lid part has a first surface opposing to the opening portion and a second surface intersecting with the first surface,
when the lid part is seen from a side of the container part, the second surface is opposed to an outer edge of the container part, and
the joining agent is disposed between the first surface and the container part, and between the second surface and the container part.

8. An optical device according to claim 7,
wherein the optical element is an optical sensor.

9. An electronic device in which an electronic element is disposed in a package,
the package comprising:
a container part having an opening portion;
a lid part that covers the opening portion; and
a joining agent disposed between the container part and the lid part,
wherein the lid part has a first surface opposing to the opening portion and a second surface intersecting with the first surface,
when the lid part is seen from a side of the container part, the second surface is opposed to an outer edge of the container part, and
the joining agent is disposed between the first surface and the container part, and between the second surface and the container part.

10. An electronic apparatus having an electronic device according to claim 9.
